(19) United States
(12) Patent Application Publication
(10) Pub. No.: US 2017/0277232 A1
(43) Pub. Date: Sep. 28, 2017

(54) INFORMATION PROCESSING APPARATUS, METHOD FOR DETECTING AIR INTAKE FAULT, AND STORAGE MEDIUM

(71) Applicant: FUJITSU LIMITED, Kawasaki-shi (JP)

(72) Inventors: Makoto YAMASHITA, Kawasaki (JP); Tatsuya Kawasumi, Yokohama (JP); Tsuyoshi Ohigawa, Kawasaki (JP)

(73) Assignee: FUJITSU LIMITED, Kawasaki-shi (JP)

(21) Appl. No.: 15/419,354

(22) Filed: Jan. 30, 2017

(30) Foreign Application Priority Data
Mar. 24, 2016 (JP) 2016-060938

(51) Int. Cl. G06F 1/20; G05D 23/19; H05K 7/20

(52) U.S. Cl. CPC G06F 1/20; H05K 7/20172; H05K 7/20145; G05D 23/1917

(57) ABSTRACT

An information processing apparatus that includes a housing provided with a dust filter, the information processing apparatus includes a first temperature sensor that measures an internal temperature of the housing; a second temperature sensor that measures an external temperature of the housing; and a processor configured to acquire an amount of information processing of the information processing apparatus, identify a first amount of temperature change resulting from information processing of the information processing apparatus based on the amount of information processing, acquire the internal and external temperatures, calculate a second amount of temperature change resulting from an air intake fault of the dust filter by subtracting the first amount of temperature change from a temperature difference between the internal temperature and the external temperature, calculate a rate of increase in the second amount of temperature change, and output a fault notification according to the calculated rate of increase.

### CROSS-REFERENCE TO RELATED APPLICATION

This application is based upon and claims the benefit of priority of the prior Japanese Patent Application No. 2016-060938, filed on Mar. 24, 2016, the entire contents of which are incorporated herein by reference.

### FIELD

The embodiments discussed herein are related to an information processing apparatus, a method for detecting an air intake fault, and a storage medium.

### BACKGROUND

An information processing apparatus includes components that generate heat when being energized, such as a central processing unit (CPU) and hard disk drive. Such overheating of a component is a factor leading to malfunction and failure. Therefore, in some cases, in order to produce a flow of air inside the apparatus to cool components, a fan is disposed inside the information processing apparatus, and an air intake port and an air outlet port are provided in the housing of the information processing apparatus. The air intake port and the air outlet port are provided with dust filters in some cases in order for waste particles, such as those of dust and dirt, not to flow to the inside of an information processing apparatus.

In a dust filter, the longer the operating time of the information processing apparatus, the larger the amount of dust and dirt accumulating in an opening portion of the filter. This causes the dust filter to be more likely to become clogged. Once the dust filter becomes clogged, the flow of air is obstructed. Therefore, the cooling efficiency decreases, and the temperature of the inside of the information processing apparatus rises. Therefore, the user, such as an operator, of an information processing apparatus cleans a dust filter or replaces the dust filter with new one regularly or when desired.

As a method of notifying the user of the timing at which the dust filter is to be cleaned or to be replaced with new one, a method using a timer that issues a notification at the time point when a given operating time period has passed is proposed. However, with the timer, a notification is issued in some cases even when the dust filter is not clogged. This leads to the occurrence of a work that is non-urgent and unnecessary for the user.

Disclosed as a method to detect clogging of a dust filter is a technique in which the temperature of a heating device within a printer apparatus is detected, the gradient of temperature change is determined, and the temperature and the gradient are compared with respective thresholds to determine whether or not and to what degree the filter is clogged. As examples of the related art, Japanese Laid-open Patent Publication No. 2014-167949, Japanese Laid-open Patent Publication No. 2004-263989, Japanese Laid-open Patent Publication No. 2012-199707, and so on are disclosed.

Clogging of a dust filter is broadly classified as (1) clogging that occurs in such a way that ultra-small waste particles, such as those of dust and dirt, accumulate in a dust filter and (2) clogging that occurs in such a way that waste particles, such as a piece of paper and a piece of vinyl, which are larger than dust or dirt particles are absorbed into a dust filter. In the case (1), the degree of urgency is relatively low, and thus it is not necessarily desired to immediately proceed to the location to address the situation. However, in the case (2), the clogging leads to failure of the apparatus, and therefore it is desired in many cases to immediately address the situation. In such a manner, the degree of urgency differs depending on the type of clogging. Therefore, it is desirable for an operator of an information processing apparatus that the operator is able to detect an air intake fault in a condition that the type of clogging is classified.

### SUMMARY

According to an aspect of the invention, an information processing apparatus that includes a housing provided with a dust filter, the information processing apparatus includes a first temperature sensor that measures an internal temperature of the housing; a second temperature sensor that measures an external temperature of the housing; and a processor configured to: acquire an amount of information processing of the information processing apparatus, identify a first amount of temperature change resulting from information processing of the information processing apparatus based on the amount of information processing, acquire the internal temperature and the external temperature, calculate a second amount of temperature change resulting from an air intake fault of the dust filter by subtracting the first amount of temperature change from a temperature difference between the internal temperature and the external temperature, calculate a rate of increase in the second amount of temperature change, and output a fault notification according to the calculated rate of increase.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of a functional block diagram of a system in a first embodiment;

FIG. 2 is a diagram illustrating an example of a hardware configuration of an information processing apparatus in the first embodiment;

FIG. 3 is a perspective view of the information processing apparatus;

FIG. 4 is a flowchart illustrating an example of a method for detecting an air intake fault in the first embodiment;

FIG. 5 is a graph depicting an example of the relationship between the power consumption and the amount of temperature change resulting from information processing;

FIG. 6 is a graph depicting an example of temporal changes in the rate of increase in the amount of temperature change resulting from an air intake fault;

FIG. 7 is a graph depicting an example of temporal changes in the amount of temperature change resulting from an air intake fault;

FIG. 8 is a diagram illustrating an example of a functional block diagram of a system in a second embodiment;

FIG. 9 is a diagram illustrating an example of a hardware configuration of an information processing apparatus in the second embodiment;

FIG. 10 is a flowchart illustrating an example of a method for detecting an air intake fault in the second embodiment;

FIG. 11 is a diagram illustrating an example of a functional block diagram of a system in a third embodiment; and

FIG. 12 is a flowchart illustrating an example of a method for detecting an air intake fault in the third embodiment.

### DESCRIPTION OF EMBODIMENTS

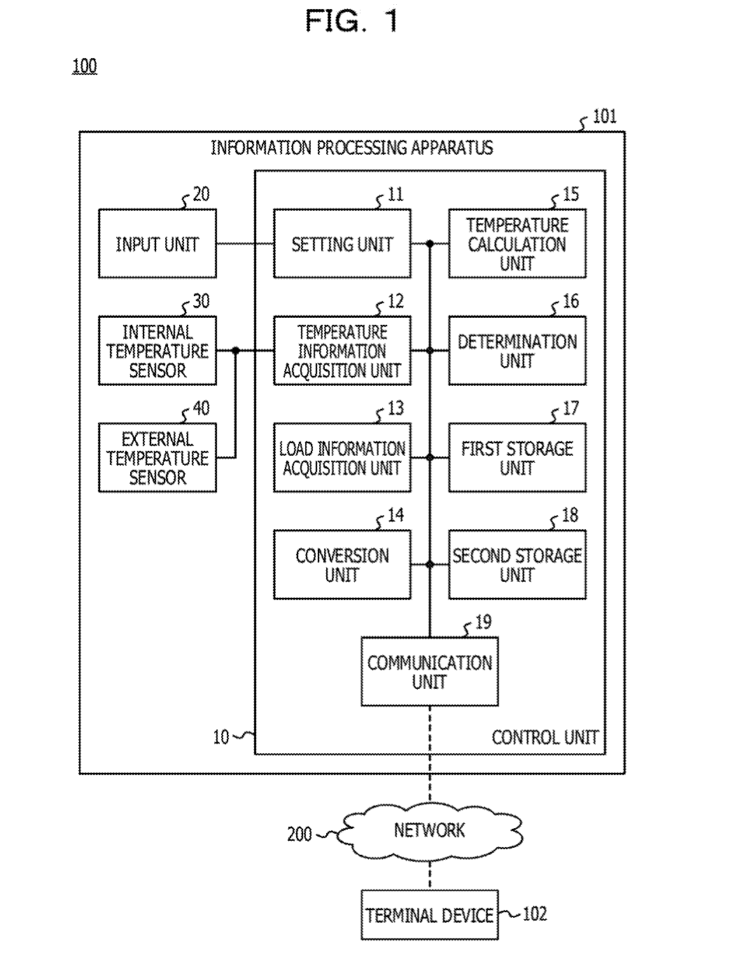

Hereinafter, embodiments of the present disclosure will be described in detail with reference to FIG. 1 to FIG. 12.

### First Embodiment

FIG. 1 is a diagram illustrating an example of a functional block diagram of a system in a first embodiment. As illustrated in FIG. 1, a system 100 includes an information processing apparatus 101 and a terminal device 102. The information processing apparatus 101 and the terminal device 102 are coupled so as to be able to communicate with each other over a network 200. The information processing apparatus 101 includes a control unit 10, an input unit 20, an internal temperature sensor 30, and an external temperature sensor 40. The information processing apparatus 101 is, for example, a computer such as a server or a personal computer. The terminal device 102 is, for example, a computer such as a personal computer, a tablet, a cellular phone, or a smartphone. The functionality of components of the information processing apparatus 101 will be described below.

The control unit 10 is hardware that manages the processing of the entire information processing apparatus 101. The control unit 10 is implemented, for example, by a processor such as a CPU or a micro processing unit (MPU). The control unit 10 includes a setting unit 11, a temperature information acquisition unit 12, a load information acquisition unit 13, a conversion unit 14, a temperature calculation unit 15, a determination unit 16, a first storage unit 17, a second storage unit 18, and a communication unit 19.

The setting unit 11 executes processing of setting various parameters for use in a process of detecting an air intake fault. The setting unit 11, for example, sets a threshold Rmax of the rate of increase in the amount of temperature change resulting from an air intake fault in the information processing apparatus 101 and a threshold dTmax of the upper limit of the amount of temperature change. These thresholds are received from the input unit 20 or are acquired by the communication unit 19 via the network 200.

The temperature information acquisition unit 12 acquires information on an external temperature of the information processing apparatus measured by the external temperature sensor 40 and on an internal temperature of the information processing apparatus measured by the internal temperature sensor 30. The temperature information acquisition unit 12 is an example of a first calculation unit and a second calculation unit.

The load information acquisition unit 13 acquires information on the amount of information processing. The amount of information processing is information indicating the degree of loads on the information processing apparatus 101, and is, for example, the amount of power consumption of the information processing apparatus 101 or the amount of traffic indicating the number of signals transmitted and received. When the amount of traffic is used as the amount of information processing, the load information acquisition unit 13 may be implemented by not only a CPU or an MPU but also by a known monitor for the amount of traffic. For example, as an example of a monitor for the amount of traffic, a statistical information processing circuit including a hardware (HW) counter for each communication path is disclosed. With this statistical information processing circuit, statistical information on the amount of traffic for each communication path may be acquired at a given time interval by using an HW counter (for example, see Japanese Laid-open Patent Publication No. 2012-199707).

The conversion unit 14 converts the amount of information processing of the information processing apparatus 101 acquired by the load information acquisition unit 13 into the amount of temperature change, dTc, which results from information processing. The method of conversion will be described below.

Based on the external temperature and the internal temperature acquired by the temperature information acquisition unit 12, the temperature calculation unit 15 calculates the amount of temperature change, dT, which results from an air intake fault, and the rate of increase, R, in the amount of temperature change dT. The method of calculation will be described below.

The determination unit 16 executes various kinds of determination processing performed in the process of detecting an air intake fault.

The first storage unit 17 is hardware that stores an air intake fault detection program for detecting an air intake fault, the program being executed by the control unit 10.

The second storage unit 18 is hardware used as a data base (DB) for storing various types of information for use in processing executed by the control unit 10. The second storage unit 18 is capable of storing a threshold Rmax of the rate of increase in the amount of temperature change resulting from an air intake fault set by the setting unit 11, a threshold Timax of the upper limit of the internal temperature of the information processing apparatus 101, and information on the amount of information processing acquired by the load information acquisition unit 13. The second storage unit 18 is capable of storing information on the amount of temperature change dTc resulting from the amount of information processing, which is calculated by the conversion unit 14, and the amount of temperature change dT resulting from an air intake fault and the rate of increase R in the amount of temperature change dT, which are calculated by the temperature calculation unit 15. These various types of information will be described below. The first storage unit 17 and the second storage unit 18 may be made up of a plurality of storage devices in accordance with applications or desirable storage capacity.

The communication unit 19 executes processing of outputting a detection result of an air intake fault. The communication unit 19, for example, may transmit a plurality of fault notifications with different degrees of urgency to the terminal device 102. Furthermore, the communication unit 19 may receive the threshold Rmax of the rate of increase R in the amount of temperature change dT resulting from an air intake fault and the threshold dTmax of the upper limit of the amount of temperature change dT, from an information processing apparatus such as the terminal device coupled to the network 200. The communication unit is an example of an output unit.

Subsequently, the input unit 20, the internal temperature sensor 30, and the external temperature sensor 40, which are coupled to the control unit 10 will be described.

The input unit 20 is an input interface that accepts input of information from the user. The input unit 20 is, for example, a keyboard, a touch panel, a mouse, or the like. The input unit 20 is coupled to the setting unit 11 and is capable of transmitting information input from the user to the setting unit 11.

The internal temperature sensor 30 is provided on the side of an air outlet port of the information processing apparatus 101 and is capable of measuring the temperature of air that moves from the side of an air intake port to the air outlet port side as an internal temperature. The internal temperature sensor 30 is coupled to the temperature information acquisition unit 12 and is capable of transmitting information on the measured internal temperature to the temperature information acquisition unit 12.

The external temperature sensor 40 is provided on the air intake port side of the information processing apparatus 101 and is capable of measuring the temperature of air coming from the air intake port as an external temperature. The external temperature sensor 40 is coupled to the temperature information acquisition unit 12 and is capable of transmitting information on the measured external temperature to the temperature information acquisition unit 12.

Next, the hardware configuration of the information processing apparatus 101 will be described.

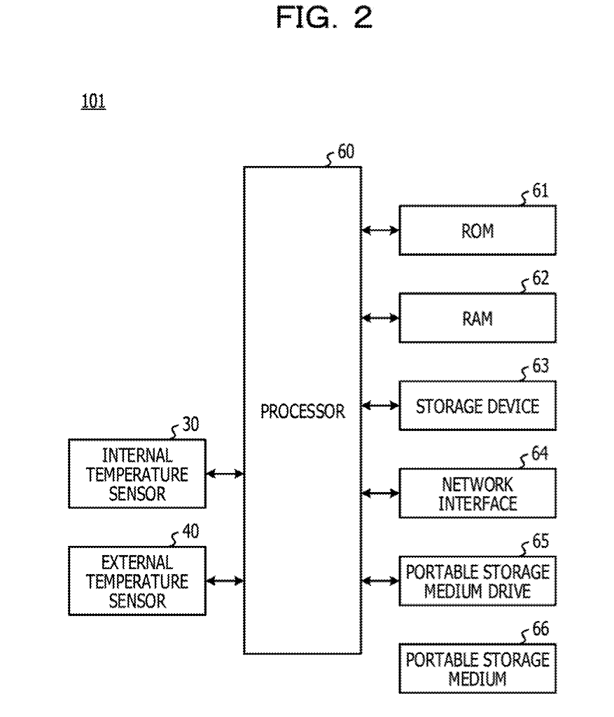

FIG. 2 is a diagram illustrating an example of a hardware configuration of an information processing apparatus in the first embodiment. As illustrated in FIG. 2, the information processing apparatus 101 includes a processor 60, read-only memory (ROM) 61, random access memory (RAM) 62, a storage device 63, a network interface 64, a portable storage medium drive 65, a portable storage medium 66, and so on.

The processor 60 is a processing device that executes processing of controlling operations of the entire information processing apparatus 101. The processor 60 may be implemented, for example, by a processor such as a CPU or an MPU. The processor 60 is an example of the control unit 10 illustrated in FIG. 1.

The ROM 61 is a nonvolatile storage device capable of storing programs that control operations of the information processing apparatus 101 (including an air intake fault detection program). The ROM 61 is an example of the first storage unit 17 illustrated in FIG. 1.

The RAM 62 is a volatile storage device capable of being used as a work area as desired when a program is executed. The RAM 62 may be provided inside the processor 60. The RAM 62 is an example of the second storage unit 18 illustrated in FIG. 1.

The storage device 63 is a large-capacity storage device, and is, for example, a hard disk drive (HDD). The storage device 63 is an example of the first storage unit 17 or the second storage unit 18 illustrated in FIG. 1.

The network interface 64 is hardware for use as an interface when communication with an external device, such as an information processing apparatus or a storage device, is performed via the network 200. The network interface 64 is, for example, a network interface card (NIC). The network interface 64 is an example of the communication unit 19 illustrated in FIG. 1.

The portable storage medium drive 65 is hardware designed to allow the portable storage medium 66 to be inserted therein or to be removed therefrom. The portable storage medium drive 65 is capable of reading various types of data and programs (including the air intake fault detection program) stored in the portable storage medium 66 and writing data to the portable storage medium 66. The portable storage medium 66 is an example of the first storage unit 17 or the second storage unit 18 illustrated in FIG. 1.

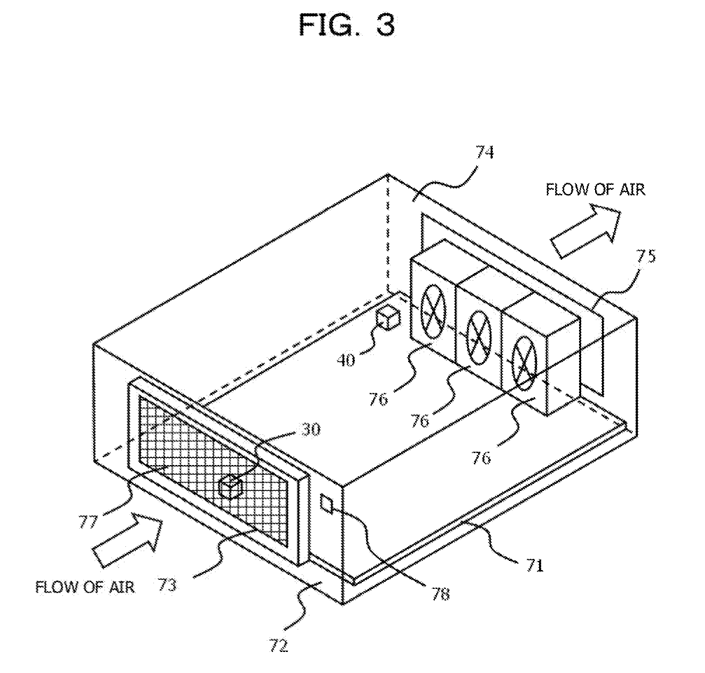

FIG. 3 is a perspective view of the information processing apparatus. In FIG. 3, the flow of air is indicated by arrows. The information processing apparatus 101 includes a printed circuit board 71 inside the housing. Many pieces of hardware included in the information processing apparatus 101 are implemented on the printed circuit board 71 but are not illustrated for the sake of explanatory convenience.

As illustrated in FIG. 3, a side face 72 of the housing includes an opening called an air intake port 73. Additionally, a side face 74 facing the side face 72 includes an opening called an air outlet port 75. A plurality of fans 76 are arranged on the surface on the side of the air outlet port 75 of the printed circuit board 71. The air intake port 73 is provided with a dust filter 77 in such a manner that the opening of the air intake port 73 is covered with the dust filter 77. By the operation (for example, rotation) of the plurality of fans 76, an airflow is generated in which external air passes through the air intake port 73, enters the inside of the information processing apparatus 101, passes through the air outlet port 75, and is discharged to the outside. With this airflow, it is possible to cool a plurality of components that generate heat within the information processing apparatus 101. At this point, the dust filter 77 is responsible for inhibiting waste particles such as dust and dirt particles contained in air of the outside that have come from the air intake port 73 from entering the inside of the information processing apparatus 101.

The external temperature sensor 40 is disposed on the surface on the side of the air intake port 73 of the printed circuit board 71. The external temperature sensor 40 is arranged to overlap the air intake port 73 as viewed from the side of the air outlet port 75 toward the air intake port 73. According to this arrangement way, the external temperature sensor 40 is close to the air intake port 73, and air that has just flown through the air intake port 73 from the outside directly strikes the external temperature sensor 40. Therefore, a temperature approximately equal to the external temperature may be measured.

Additionally, the internal temperature sensor 30 is disposed on the surface on the side of the air outlet port 75 of the printed circuit board 71. The internal temperature sensor 30 is arranged not to overlap the fans 76 as viewed from the side of the air intake port 73 toward the air outlet port 75. Such arrangement enables cooling of the internal temperature sensor 30 by using an airflow to be kept to a minimum level, enabling the highest internal temperature within the housing to be measured. This place where the internal temperature sensor 30 is arranged is suitable for monitoring a temperature error in the inside of the information processing apparatus 101.

Additionally, an output terminal 78 is provided on the side face 72 of the housing. The output terminal 78 is part of the communication unit 19 and is used as a terminal for coupling with the terminal device 102 via the network 200.

Next, a method for detecting an air intake fault executed by the information processing apparatus 101 illustrated in FIG. 1 in the first embodiment will be described.

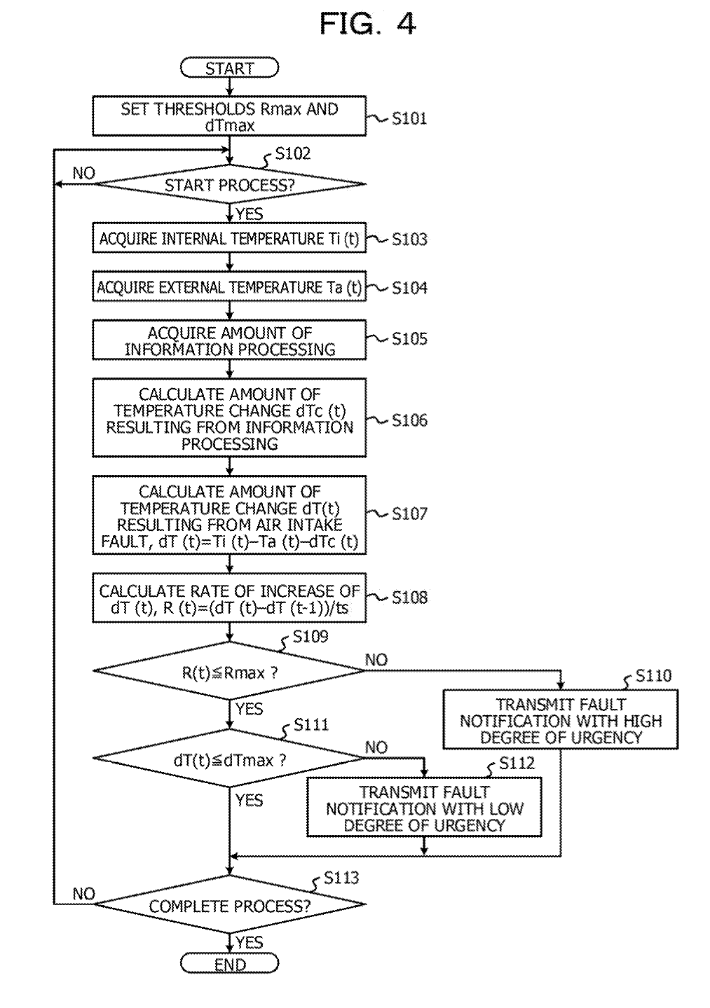

FIG. 4 is a flowchart illustrating an example of a method for detecting an air intake fault in the first embodiment.

First, the setting unit 11 sets the threshold Rmax of the upper limit of the rate of increase R in the amount of temperature change dT resulting from an air intake fault and the threshold dTmax of the upper limit of the amount of temperature change resulting from the air intake fault (S101). In particular, the setting unit 11 receives information on Rmax and dTmax input to the input unit 20 and stores the received information in the second storage unit 18, thereby setting the thresholds. Alternatively, the thresholds may be set in such a way that the communication unit 19 receives information on Rmax and dTmax transmitted from another device via the network 200 and that the setting unit 11 stores the received information in the second storage unit 18. The way to calculate the rate of increase R in the amount of temperature change dT resulting from an air intake fault will be described below.

Subsequently, the determination unit 16 determines whether or not to start a process of detecting an air intake fault (S102). For example, when the information processing apparatus 101 is powered on to start operating, the determination unit 16 determines whether or not to start the process of detecting an air intake fault. Alternatively, when a process of detecting an air intake fault is executed at a given time interval, the determination unit 16 determines whether or not to start the process of detecting an air intake fault by determining whether or not a given time period has passed after completion of the previous series of operations. The given time period is, for example, three to four minutes.

If it is determined not to start the process of detecting an air intake fault (No in S102), the process in S102 is executed again. However, if it is determined to start the process of detecting an air intake fault (Yes in S102), the temperature information acquisition unit 12 acquires information on an internal temperature Ti (t) from the internal temperature sensor 30 (S103). Here, t is a parameter representing a time point at which the process is executed.

Subsequently, the temperature information acquisition unit 12 acquires information on an external temperature Ta (t) from the external temperature sensor 40 (S104).

Subsequently, the load information acquisition unit 13 acquires information on the amount of information processing at the time t (S105). The information on information processing is, for example, the power consumption or the amount of traffic. The amount of traffic is, for example, the number of received frames, the number of transmitted frames, the sum of the number of received frames and the number of transmitted frames, or the like.

Subsequently, the conversion unit 14 calculates the amount of temperature change dTc (t) resulting from information processing (S106).

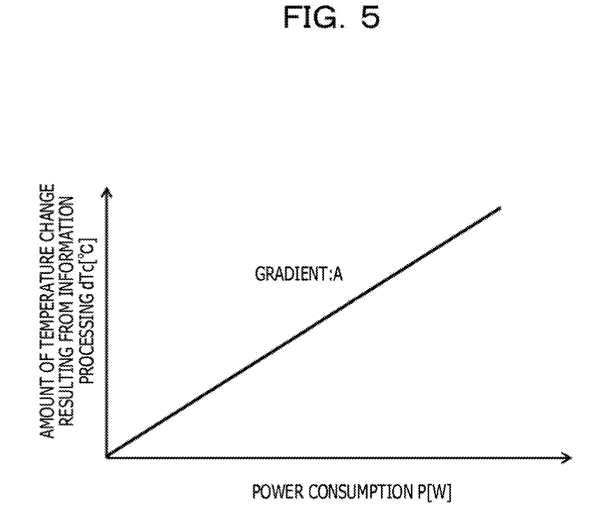

FIG. 5 is a diagram depicting an example of the relationship between the power consumption and the amount of temperature change resulting from information processing. In the case of a transmission device, for example, the larger the amount of signals transmitted and received (the amount of traffic), the larger the load of information processing, and thus the power consumption increases. In addition, as depicted in FIG. 5, there is a proportionality between the power consumption P and the amount of temperature change dTc resulting from information processing. Not illustrated in the drawing, there is also a proportionality between the amount of traffic and the amount of temperature change resulting from information processing. Accordingly, the information processing apparatus 101 in advance acquires information on the correspondence between the amount of information processing and the amount of temperature change dTc resulting from information processing. In S106, based on this correspondence, the conversion unit 14 converts the amount of information processing acquired by the load information acquisition unit 13 to the amount of temperature change dTc (t) resulting from information processing at the time point t. When power consumption is used as the amount of information processing, the information on the correspondence may be expressed by a transformation, for example, as given as expression (1) below. That is, a constant A denotes the gradient of the graph depicted in FIG. 5.

dTc(t)=A×P(t), Expression (1):

where P(t) is the power consumption at the time point t, and A is a constant.

For example, assuming that P (t)=300 W, and A=0.06, the amount of temperature change dTc (t) resulting from information processing at the time t is calculated as dTc (t)=300×0.06=18° C. The transformation is not limited to a linear expression such as expression (1), and a high-degree expression, such as a quadratic expression or a cubic expression, or a polynomial expression including any of these expressions may be used. As the information on the correspondence, in addition to the transformation, a correspondence table representing the relationship between the amount of information processing and the amount of temperature change dTc resulting from information processing may be used.

Referring back to FIG. 4, after the process in S106, the temperature calculation unit 15 calculates the amount of temperature change dT (t) resulting from an air intake fault at the time t (S107). The temperature difference between the inside and the outside of the information processing apparatus 101 at the time t may be calculated by Ti (t)−Ta (t), which is a difference between the internal temperature Ti (t) and the external temperature Ta (t).

Here, the temperature rise of the information processing apparatus 101 is assumed to be dependent on two factors, information processing and an air intake fault. In this case, the amount of temperature change dT (t) resulting from an air intake fault at the time point t may be calculated by subtracting the amount of temperature change dTc (t) resulting from information processing from the temperature difference between the inside and the outside of the information processing apparatus 101. That is, the amount of temperature change dT (t) resulting from an air intake fault may be calculated by subtracting the amount of temperature change dTc (t) resulting from information processing from the difference between the internal temperature Ti (t) and the external temperature Ta (t), as expressed by expression (2) given below.

dT(t)=Ti(t)−Ta(t)−dTc(t) Expression (2):

For example, assuming that Ti (t)=50° C., Ta (t)=25° C., and dTc (t)=18° C., dT (t) is calculated as dT (t)=50−25−18=7° C.

After the process in S107, the temperature calculation unit 15 calculates the rate of increase R (t) in the amount of temperature change resulting from an air intake fault (S108). The rate of increase in the amount of temperature change resulting from an air intake fault is the amount of change of dT per unit time period. Assuming that the “given time period” described in S102 is a unit time period ts, the rate of increase R (t) per unit time period in the amount of temperature change resulting from an air intake fault may be expressed by expression (3) given below.

R(t)=(dT(t)−dT(t−1))/ts, Expression (3):

where the time point t−1 is a time point that is prior to the time point t by the given time period ts.

After the process in S108, the determination unit 16 determines whether or not the rate of increase R (t) in the amount of temperature change resulting from an air intake fault is less than or equal to the threshold Rmax set in S101 (S109).

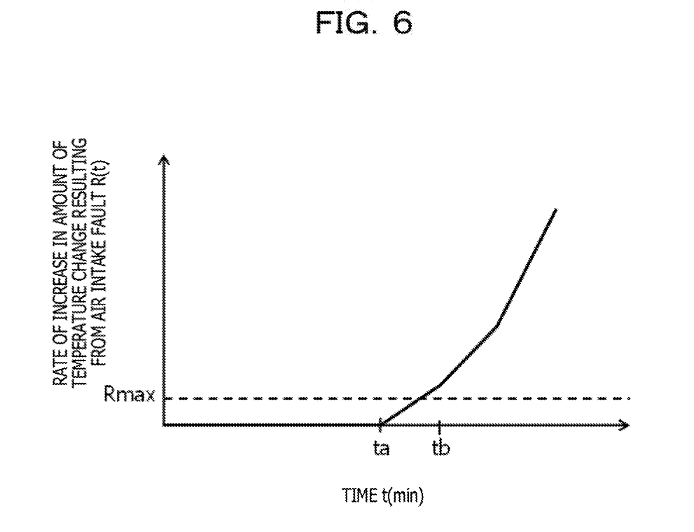

FIG. 6 is a diagram depicting an example of temporal changes in the rate of increase in the amount of temperature change resulting from an air intake fault. The horizontal axis represents time t (in units of minutes), and the vertical axis represents the rate of increase R (t) in the amount of temperature change resulting from an air intake fault. The level of the threshold Rmax of the upper limit of the rate of increase R is indicated by the dotted line.

As depicted in FIG. 6, R (t) stays at zero or a numerical value close to zero from the instance at which the information processing apparatus 101 starts operating until a time point ta. However, R (t) abruptly increases after the time point ta. At a time point tb, R (t) exceeds the dotted-line level indicating the threshold Rmax. From the temporal changes depicted in FIG. 6, it may be inferred that waste particles, such as a piece of paper or a piece of vinyl, larger than dust or dirt particles were absorbed into a dust filter at around the time point ta. When the determination processing in S109 is executed by using R (t), for example, at the time point t=tb, R (t) is greater than Rmax. Therefore, the determination unit 16 determines that R (t) is not less than or equal to Rmax (No in S109).

Referring back to FIG. 4, if it is determined that R (t) is not less than or equal to Rmax (No in S109), it is determined that waste particles larger than dust or dirt particles have been absorbed into the dust filter. The communication unit 19 transmits a fault notification of a high degree of urgency to the terminal device 102 via a network (S110). Through the process in S110, an operator of the information processing apparatus 101 receives the fault notification of the high degree of urgency via the terminal device 102 and recognizes that waste particles larger than dust or dirt particles have been absorbed into the dust filter of the information processing apparatus 101 and thus clogging has occurred. This allows the operator to proceed to the location of the information processing apparatus 101 and quickly perform a recovery operation. After S110, the process proceeds to S113.

On the other hand, if it is determined that R (t) is less than or equal to Rmax (Yes in S109), the determination unit 16 determines that clogging with a high degree of urgency has not occurred in the dust filter of the information processing apparatus 101, and the process proceeds to S111. In order to determine whether or not clogging with a low degree of urgency caused by accumulation of ultra-small waste particles, such as dust and dirt particles, has occurred, the determination unit 16 determines whether or not the amount of temperature change dT (t) caused by an air intake fault is less than or equal to the threshold dTmax of the upper limit set in S101 (S111).

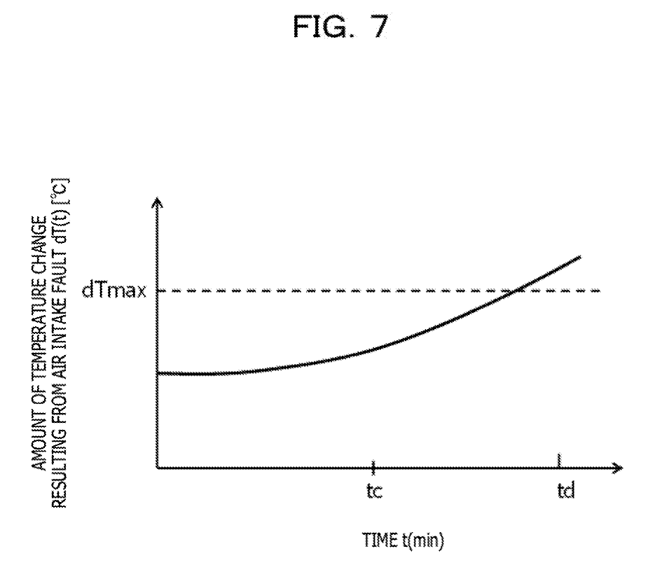

FIG. 7 is a diagram depicting an example of temporal changes in the amount of temperature change resulting from an air intake fault. The horizontal axis represents time t, and the vertical axis represents the amount of temperature change dT (t) resulting from an air intake fault. The level of the threshold dTmax of the upper limit of dT (t) is indicated by the dotted line.

As depicted in FIG. 7, dT (t) represents a tendency to increase while drawing a gentle curve line. At a time point tc, dT (t) does not exceed the dotted-line level indicating the threshold dTmax; however, at a time point td, dT (t) exceeds the dotted-line level. Therefore, when the determination processing in S111 is executed by using dT (t), for example, at the time point t=tc, it is determined that dT (t) is less than or equal to dTmax (Yes in S111), that is, that dT (t) does not exceed dTmax. In contrast, when the determination processing in S111 is executed by using dT (t), for example, at the time point t=td, it is determined that dT (t) is not less than or equal to dTmax (No in S111), that is, that dT (t) exceeds dTmax.

Referring back to FIG. 4, it is determined that dT (t) is not less than or equal to dTmax (No in S111), it is determined that clogging due to ultra-small waste particles exceeds a permissible range. The communication unit 19 transmits a fault notification with a low degree of urgency to the terminal device 102 via a network (S112). Through the process in S112, an operator of the information processing apparatus 101 receives a fault notification of a low degree of urgency via the terminal device 102. Thus, the operator recognizes that since ultra-small waste particles have accumulated in the dust filter of the information processing apparatus 101, the dust filter is to be cleaned or replaced in the near future. This enables the operator to proceed to the location of the information processing apparatus 101 and to perform restoration work at a suitable time in accordance with the degree of urgency. After S112, the process proceeds to S113.

However, if dT (t) is less than or equal to dTmax (Yes in S111), the determination unit 16 determines that clogging due to ultra-small waste particles is within the permissible range, and the process proceeds to S113.

In S113, the determination unit 16 determines whether or not to complete the process for detecting an air intake fault. If it is determined that the process is not to be completed (No in S113), the process returns to S102, where the process in and after S102 is executed again. However, for example, when the determination unit 16 detects that the information processing apparatus 101 is executing processing of stopping operation, the determination unit 16 determines that the process is to be completed (Yes in S113). Then, the control unit 10 completes a series of operations for detecting an air intake fault.

In a way as described above, the process relevant to the method for detecting an air intake fault may be executed.

According to the first embodiment, an amount of temperature change resulting from an air intake fault is obtained by subtracting an amount of temperature change resulting from information processing from a difference between an internal temperature and an external temperature of the information processing apparatus, and the value of the amount of temperature change and the rate of increase are compared with respective thresholds. Thus, an air intake fault is detected in a condition that the type of clogging of the dust filter is classified. According to this method, the determination process is performed with the use of the rate of increase in the amount of temperature change resulting from an air intake fault, and therefore the air intake fault may be detected in a condition that the type of clogging is classified.

Furthermore, according to this method, with the amount of temperature change resulting from information processing excluded, the amount of temperature change resulting from an air intake fault is extracted. Therefore, an air intake fault may be detected with high accuracy.

### Second Embodiment

Next, a second embodiment will be described. The second embodiment has a feature in that when clogging of the dust filter is detected, a fault notification is output from an output unit provided in an apparatus where the dust filter is provided.

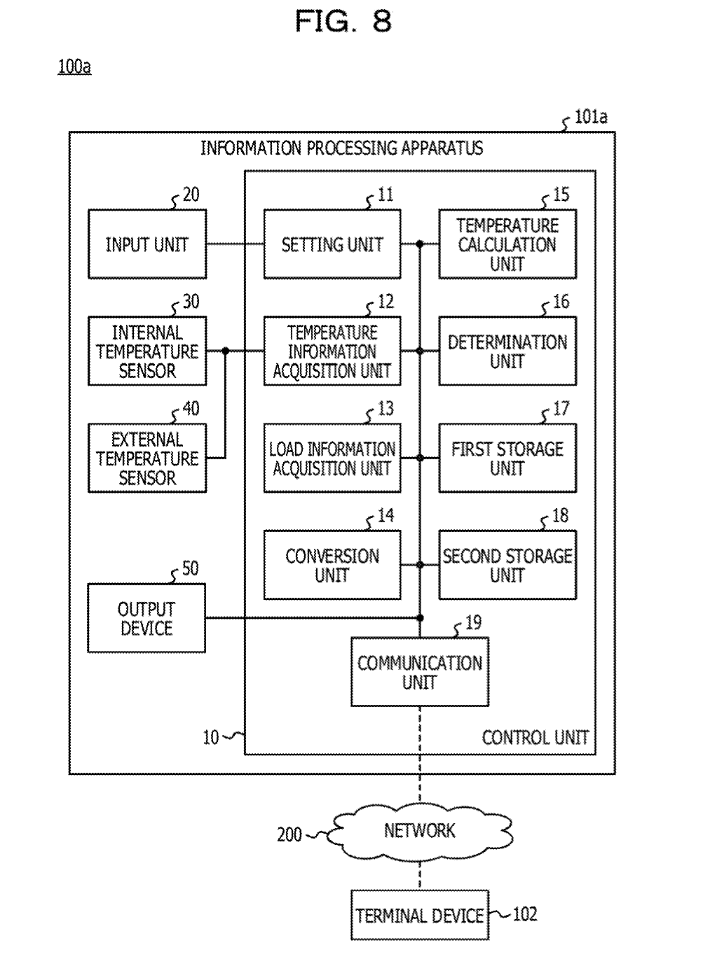

Hereinafter, the second embodiment will be described with reference to FIG. 8 to FIG. 10.

FIG. 8 is a diagram illustrating an example of a functional block diagram of a system. As illustrated in FIG. 8, a system 100a includes at least an information processing apparatus 101a. Like the system 100 in the first embodiment, the system 100a may include the terminal device 102. When the system 100a includes the terminal device 102, the information processing apparatus 101a and the terminal device 102 are coupled so as to be able to communicate with each other, for example, over the network 200. The information processing apparatus 101a includes an output unit 50 coupled to the control unit 10.

The output unit 50 is capable of outputting an alarm in accordance with the degree of urgency of an air intake fault when the air intake fault is detected by the determination unit 16. Other functional blocks constituting the system 100a are similar to the functional blocks denoted by the same reference numerals in the first embodiment illustrated in FIG. 1, and description thereof is omitted.

Next, the hardware configuration of the information processing apparatus 101a will be described.

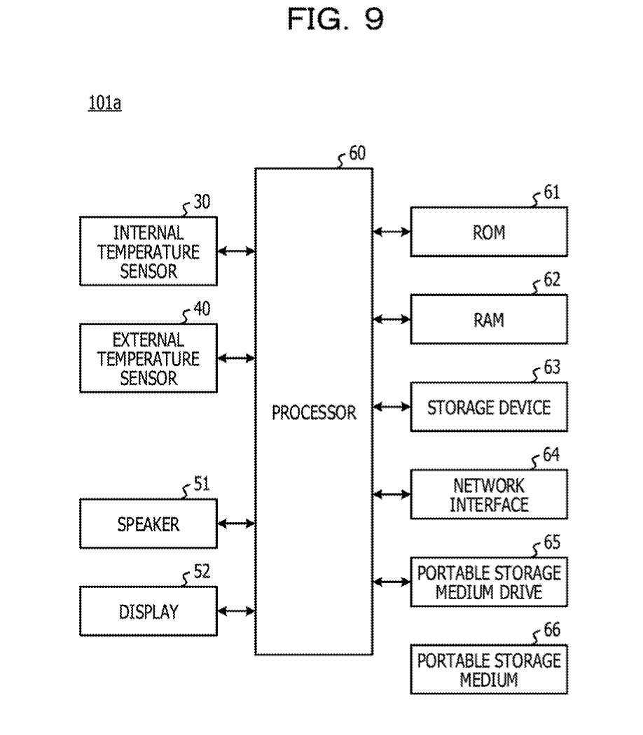

FIG. 9 is a diagram illustrating an example of a hardware configuration of an information processing apparatus in the second embodiment. As illustrated in FIG. 9, the information processing apparatus 101a includes, in addition to hardware illustrated in FIG. 2, a speaker 51 and a display 52. The speaker 51 and the display 52 are examples of the output unit 50 illustrated in FIG. 8.

The speaker 51 is a device for outputting sound such as alert sound or voice. The display 52 is a device for displaying characters, images or pictures. The display 52 is implemented, for example, by a liquid crystal display, a plasma display, an organic electroluminescent (EL) display, or the like. Other pieces of hardware constituting the information processing apparatus 101a are similar to the pieces of hardware denoted by the same reference numerals in the first embodiment illustrated in FIG. 2, respectively, and description thereof is omitted.

Next, a method for detecting an air intake fault executed by the information processing apparatus 101a illustrated in FIG. 8 in the second embodiment will be described.

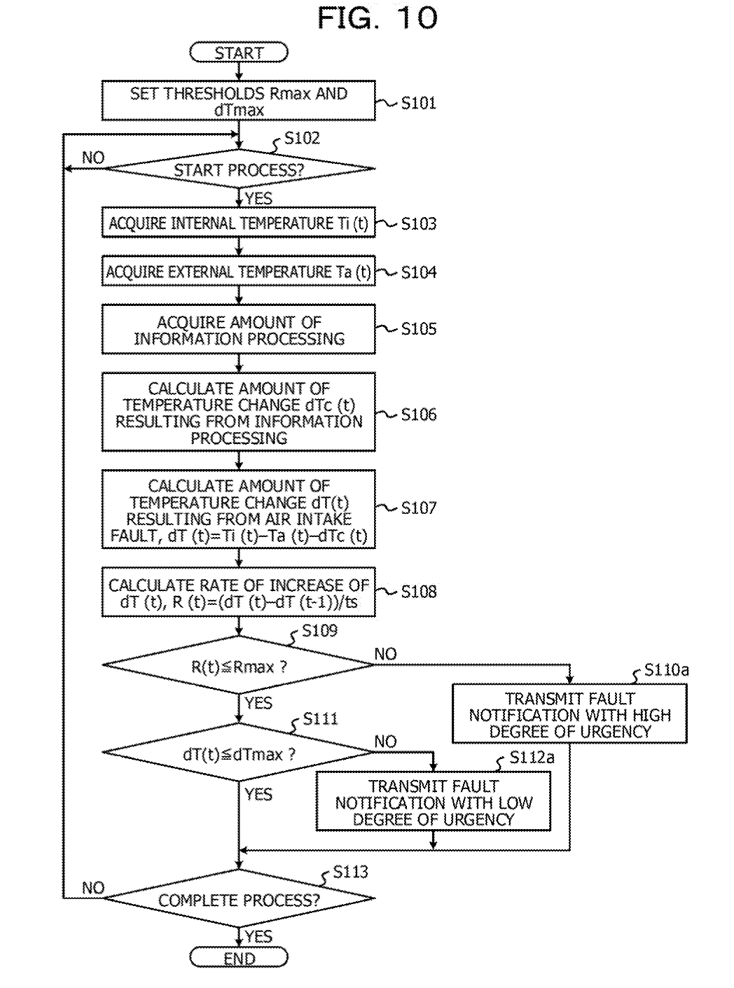

FIG. 10 is a flowchart illustrating an example of a method for detecting an air intake fault in the second embodiment. The process from S101 to S109 is similar to the process from S101 to S109 in the first embodiment illustrated in FIG. 4, and description thereof is omitted.

In S109, it is determined by the determination unit 16 that the rate of increase R (t) in the amount of temperature change resulting from an air intake fault is not less than or equal to the threshold Rmax (No in S109), it is determined that waste particles larger than dust or dirt particles have been absorbed into the dust filter. Additionally, the output unit 50 outputs a fault notification with a high degree of urgency (S110a). When the output unit 50 is the speaker 51, the output unit 50 outputs a fault notification as alert sound or voice. In contrast, when the output unit 50 is the display 52, the output unit 50 displays a fault notification on a screen. The process in S110a allows the operator of the information processing apparatus 101 to auditorily or visually recognize that a fault with a high degree of urgency has occurred. After S110a, the process proceeds to S113. The process in and after S113 is similar to the process in and after S113 in the first embodiment illustrated in FIG. 4, and description thereof is omitted.

However, in S109, if it is determined by the determination unit 16 that the rate of increase R (t) in the amount of temperature change resulting from an air intake fault is less than or equal to the threshold Rmax (Yes in S109), the determination unit 16 determines that clogging with a high degree of urgency has not occurred in the dust filter of the information processing apparatus 101, and the process proceeds to S111. In order to determine whether or not clogging with a low degree of urgency caused by accumulation of ultra-small waste particles, such as dust and dirt particles, has occurred, the determination unit 16 determines whether or not the amount of temperature change dT (t) resulting from an air intake fault is less than or equal to the threshold dTmax of the upper limit set in S101 (S111).

If it is determined that dT (t) is not less than or equal to dTmax (No in S111), the determination unit 16 determines that clogging due to ultra-small waste particles exceeds the permissible range, and causes the output unit 50 to output a fault notification with a low degree of urgency (S112a). When the output unit 50 is the speaker 51, the output unit 50 outputs a fault notification with sound such as alert sound or voice. In contrast, when the output unit 50 is the display 52, the output unit 50 displays characters, an image, or a picture indicating a fault notification on a screen. This allows an operator of the information processing apparatus 101a to auditorily or visually recognize that a fault of a low degree of urgency has occurred. After S112a, the process proceeds to S113.

However, if it is determined that dT (t) is less than or equal to dTmax (Yes in S111), the determination unit 16 determines that clogging due to ultra-small waste particles is within the permissible range, and the process proceeds to S113. The process in and after S113 is similar to the process in and after S113 in the first embodiment, and description thereof is omitted.

In a way as described above, the process relevant to the method for detecting an air intake fault may be executed.

According to the second embodiment, when clogging of the dust filter is detected, a fault notification in accordance with the degree of urgency is output from the output unit 50 provided in the apparatus where the dust filter is provided. According to this method, the network 200 is not used as a notification instrument, and therefore a fault notification may be output without depending on the state of the network 200.

### Third Embodiment

Next, a third embodiment will be described. The third embodiment has a feature in that, when it is determined that waste particles larger than dust or dirt particles have been absorbed into the dust filter, the amount of time for a component that generates heat to reach an internal temperature at which the component is highly likely to fail is estimated, and the operator is notified of the estimated result together with an alert.

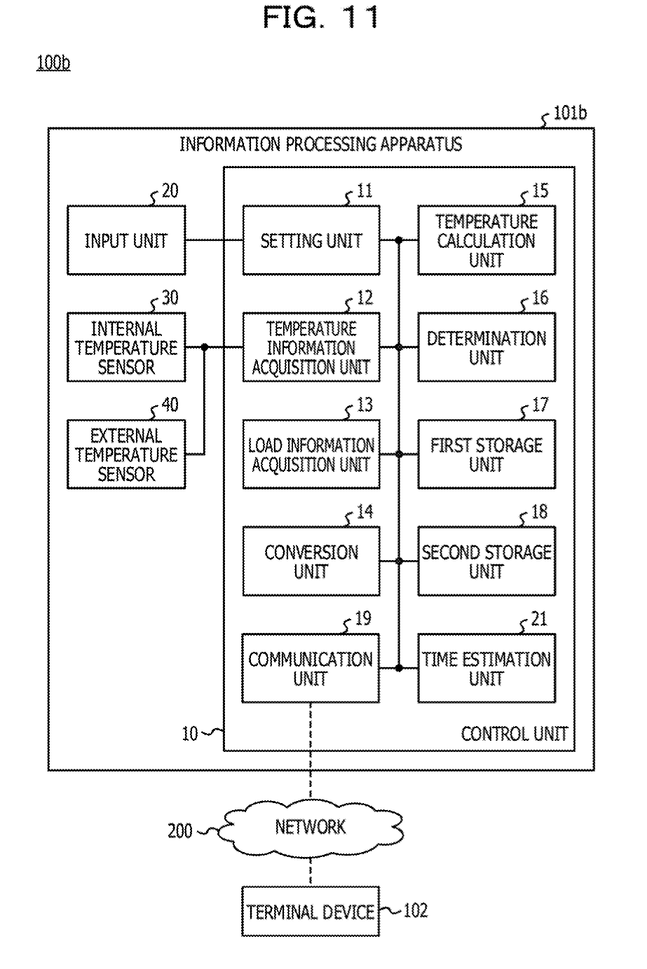

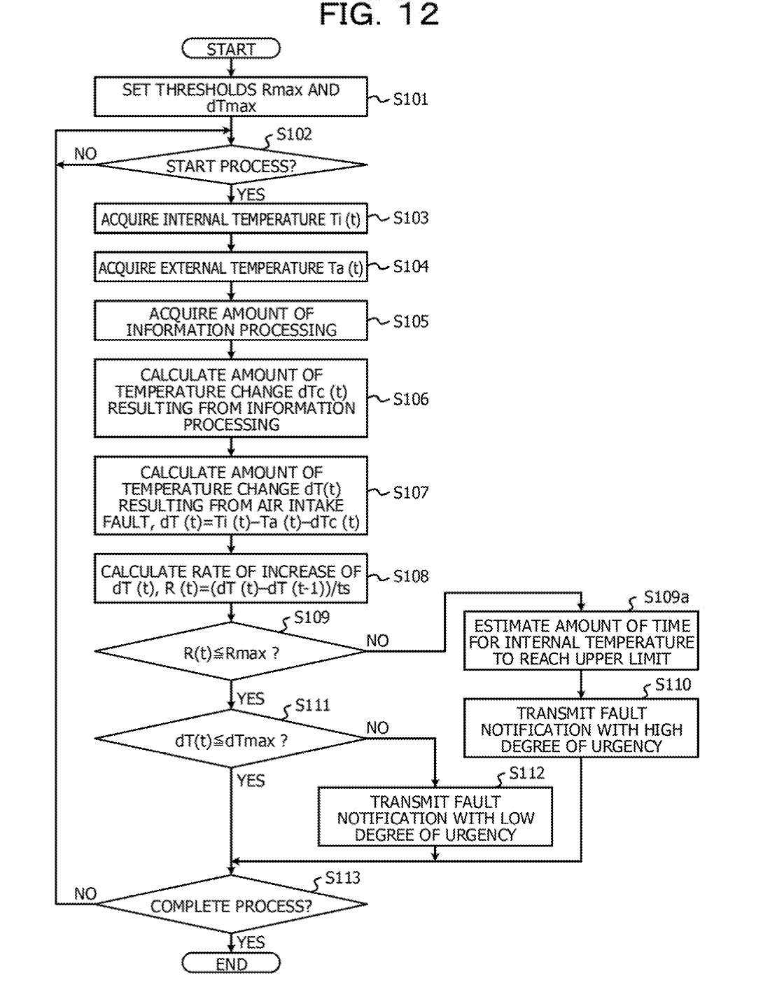

Hereinafter, the third embodiment will be described with reference to FIG. 11 and FIG. 12.

FIG. 11 is a diagram illustrating an example of a functional block diagram of a system in the third embodiment. As illustrated in FIG. 11, a system 100b includes an information processing apparatus 101b and the terminal device 102. The information processing apparatus 101b and the terminal device 102 are coupled so as to be able to communicate with each other over the network 200. The information processing apparatus 101b includes a time estimation unit 21 in the control unit 10.

The time estimation unit 21 estimates the amount of time for the internal temperature to reach the upper limit at which a component that generates heat is highly likely to fail. Other functional blocks constituting the system 100b are similar to the functional blocks denoted by the same reference numerals in the first embodiment illustrated in FIG. 1, respectively, and description thereof is omitted. The hardware configuration of the information processing apparatus 101b is similar to the hardware configuration of the information processing apparatus 101 in the first embodiment illustrated in FIG. 2, and therefore description thereof is omitted.

Next, a method for detecting an air intake fault executed by the information processing apparatus 101b illustrated in FIG. 11 in a third embodiment will be described.

FIG. 12 is a flowchart illustrating an example of the method for detecting an air intake fault in the third embodiment. The process from S101 to S109 is similar to the process from S101 to S109 in the first embodiment illustrated in FIG. 4, and description thereof is omitted.

If, in S109, it is determined that the rate of increase R (t) in the amount of temperature change resulting from an air intake fault is less than or equal to the threshold Rmax (No in S109), the time estimation unit 21 estimates the amount of time for the internal temperature of the information processing apparatus 101b to reach the upper limit (S109a). Here, a method for estimating the amount of time for the internal temperature to reach the upper limit, which is executed by the time estimation unit 21 in S109a, will be described.

First, the amount of temperature change dT (t−1) resulting from an air intake fault may be expressed by expression (4).

dT(t−1)=Ti(t−1)−Ta(t−1)−dTc(t−1) Expression (4):

Assuming that the external temperature and the amount of information processing each do not change at and after the time point t, the following expressions are given.

Ta(t)=Ta(t−1) Expression (5):

dTc(t)=dTc(t−1) Expression (6):

Thus, using expression (2) to expression (6), the rate of increase R (t) per unit time in the amount of temperature change resulting from an air intake fault may be expressed by using the internal temperature as in expression (7) given below.

R(t)=(T(t)−T(t−1))/ts=(Ti(t)−Ti(t−1))/ts Expression (7):

Subsequently, assuming that the upper limit of the internal temperature is Timax, the amount of time for the internal temperature to reach Timax is estimated.

Assuming that Timax is reached at a time point x, and the time point t is the starting point, the amount of time to reach Timax is represented as a difference from the time point x to the time point t, that is, x−t. When the rate of increase in the internal temperature is fixed, the following expression (8), which expresses that the gradients of temporal change in the internal temperature are equal, holds.

(Timax−Ti(t))/(x−t)=Ti(t)−Ti(t−1))/ts Expression (8):

Therefore, the amount of time x−t to reach Timax may be calculated by the use of the following expression (9).

x−t=ts×(Timax−Ti(t))/(T(t)−T(t−1)) Expression (9):

For example, assuming that Timax=80° C., Ti (t)=70° C., Ti (t−1)=65° C., and ts=5 min, the amount of time x−t to reach Timax is calculated as x−t=5×(80−70)/(70−65)=10 min.

In a way as described above, the amount of time to reach the upper limit of the internal temperature may be estimated.

After S109a, the process proceeds to S110. The process in and after S110 is similar to the process in and after S110 in the first embodiment, and description thereof is omitted.

In a way as described above, the method for detecting an air intake fault may be executed.

According to the third embodiment, when it is determined that waste particles larger than dust or dirt particles have been absorbed into the dust filter, the amount of time to reach an internal temperature at which a component that generates heat is highly likely to fail is estimated based on information on temporal changes in the internal temperature, and an operator is notified of the estimated result together with an alert. According to this method, the degree of urgency of an air intake fault of which the operator is notified may be represented as a specific amount of time. This allows the operator to understand the degree of urgency in more detail.

In the above, desirable embodiments of the present disclosure have been described in detail. However, the present disclosure is not limited to specific embodiments and may be modified and changed in various manners. For example, the perspective view illustrated in FIG. 3 illustrates the example in which one internal temperature sensor 30 and one external temperature sensor 40 are provided. However, two or more internal temperature sensors 30 and two or more external temperature sensors 40 may be provided. For example, a plurality of internal temperature sensors 30 may each be arranged next to a component that generates heat. According to this method, the internal temperature sensor 30 lies in very close proximity to the component that generates heat, and therefore temperature information approximately equivalent to the temperature of the component that generates heat may be acquired as an internal temperature.

In the description of the flowchart, two types of fault notifications with different levels of urgency are used as fault notifications that are output when clogging of the dust filter is detected. However, fault notifications of types at three or more levels may be used.

In the second embodiment, a fault notification is output by using either the speaker or the display; however, the outputting may be performed by using both the speaker and the display. Fault notifications are not only output from the speaker, the display, or both of them but also may be transmitted to the terminal device 102 via the network 200. According to this method, faulty notifications may be provided both to an operator who directly monitors the information processing apparatus 101b and to an operator who is at a location apart from the information processing apparatus 101b. This enables oversight or misrecognition of a fault notification to be reduced.

A computer program that causes a computer to execute the method for detecting an air intake error described above and a non-transitory computer-readable recording medium on which the program is recorded are included in the scope of the present disclosure. The non-transitory computer-readable recording medium mentioned herein is, for example, a memory card such as a secure digital (SD) card. The computer program mentioned above is not limited to that recorded on the recording medium. For example, the non-transitory computer-readable recording medium may be transmitted over a telecommunication line, a wireless or wired communication line, a network, notably the internet, or the like.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An information processing apparatus that includes a housing provided with a dust filter, the information processing apparatus comprising:
a first temperature sensor that measures an internal temperature of the housing;
a second temperature sensor that measures an external temperature of the housing; and
a processor configured to:
acquire an amount of information processing of the information processing apparatus,
identify a first amount of temperature change resulting from information processing of the information processing apparatus based on the amount of information processing,
acquire the internal temperature and the external temperature,
calculate a second amount of temperature change resulting from an air intake fault of the dust filter by subtracting the first amount of temperature change from a temperature difference between the internal temperature and the external temperature,
calculate a rate of increase in the second amount of temperature change, and
output a fault notification according to the calculated rate of increase.

2. The information processing apparatus according to claim 1, wherein the processor is configured to:
output the fault notification with a first degree of urgency when it is determined that the rate of increase is greater than a first threshold, and
output the fault notification with a second degree of urgency, the second degree of urgency being lower than the first degree of urgency, when it is determined that the rate of increase is less than or equal to the first threshold and that the second amount of temperature change is greater than a second threshold.

3. The information processing apparatus according to claim 2, further comprising
a fan;
an air intake port including a dust filter for inhibiting a foreign substance from entering from outside, the air intake port configured to take in air from outside of the information processing apparatus when the fan is in operation; and
an air outlet port provided on a face facing a face on which the air intake port is provided, the air outlet port configured to emit air taken in from the air intake port when the fan is in operation, wherein
the first temperature sensor is arranged on a side of the air outlet port of the housing, and
the second temperature sensor is arranged on a side of the air intake port of the housing.

4. The information processing apparatus according to claim 3,
wherein the first temperature sensor is arranged not to overlap the air outlet port when viewed from the side of the air intake port toward the air outlet port.

5. The information processing apparatus according to claim 3,
wherein the external temperature sensor is arranged to overlap the air intake port when viewed from the side of the air outlet port toward the air intake port.

6. The information processing apparatus according to claim 1,
wherein the processor is configured to identify the first amount of temperature change by multiplying the amount of information processing by a given coefficient.

7. The information processing apparatus according to claim 2,
wherein the processor is configured to:
calculate a time period for the internal temperature to reach an upper limit when it is determined that at least the rate of increase is greater than the first threshold, and
output, together with the calculated time period, a fault notification with the first degree of urgency.

8. The information processing apparatus according to claim 1,
wherein the first temperature sensor is arranged next to a component that generates heat among a plurality of components in the housing.

9. The information processing apparatus according to claim 1, wherein the processor is configured to identify the first amount of temperature change by referencing correspondence information indicating a correspondence between the amount of information processing and an amount of temperature change resulting from the information processing.

10. A control method executed by a processor included in an information processing apparatus that includes a housing provided with a dust filter, the control method comprising:
acquiring an internal temperature and an external temperature of the housing;
acquiring an amount of information processing of the information processing apparatus;
identifying a first amount of temperature change resulting from information processing of the information processing apparatus based on the amount of information processing;
calculating a second amount of temperature change resulting from an air intake fault of the dust filter by subtracting the first amount of temperature change from a temperature difference between the internal temperature and the external temperature;
calculating a rate of increase in the second amount of temperature change; and
outputting a fault notification according to the calculated rate of increase.

11. The control method according to claim 10, wherein the outputting includes:
outputting the fault notification with a first degree of urgency when it is determined that the rate of increase is greater than a first threshold, and
outputting the fault notification with a second degree of urgency, the second degree of urgency being lower than the first degree of urgency, when it is determined that the rate of increase is less than or equal to the first threshold and that the second amount of temperature change is greater than a second threshold.

12. A non-transitory computer-readable storage medium storing a program that causes a processor included in an information processing apparatus, the information processing apparatus including a housing provided with a dust filter, to execute a process, the process comprising:
acquiring an internal temperature and an external temperature of the housing;
acquiring an amount of information processing of the information processing apparatus;
identifying a first amount of temperature change resulting from information processing of the information processing apparatus based on the amount of information processing;
calculating a second amount of temperature change resulting from an air intake fault of the dust filter by subtracting the first amount of temperature change from a temperature difference between the internal temperature and the external temperature;
calculating a rate of increase in the second amount of temperature change; and
outputting a fault notification according to the calculated rate of increase.

13. The storage medium according to claim 12, wherein the outputting includes:
outputting the fault notification with a first degree of urgency when it is determined that the rate of increase is greater than a first threshold, and
outputting the fault notification with a second degree of urgency, the second degree of urgency being lower than the first degree of urgency, when it is determined that the rate of increase is less than or equal to the first threshold and that the second amount of temperature change is greater than a second threshold.
